(19) United States
(12) Patent Application Publication
(10) Pub. No.: US 2006/0212777 A1
(43) Pub. Date: Sep. 21, 2006

(54) Medium storage device and write path diagnosis method

(75) Inventor: Yuichi Hirao, Kawasaki (JP)

Correspondence Address: GREER, BURNS & CRAIN, 300 S WACKER DR, 25TH FLOOR, CHICAGO, IL, 60606, US

(73) Assignee: FUJITSU LIMITED

(21) Appl. No.: 11/190,146

(22) Filed: Jul. 26, 2005

(30) Foreign Application Priority Data
Mar. 14, 2005 (JP) 2005-71429

(51) Int. Cl. G11C 29/00

(52) U.S. Cl. 714/763

(57) ABSTRACT

A medium storage device writes the data on a medium by a write element and executes the diagnosis of a write system path without dropping the performance of the device. For a write command from a host, write data is stored in a data memory, a response is returned to the host, then the data is written back from the data memory to a storage medium. During this write back, partial data, including the final portion of the write data, is read from the storage medium, and the data is compared. Therefore the write system path can be diagnosed without affecting the host, and since partial data including the final portion is the target, diagnosis in a short time can be implemented, and a drop in performance can be minimized.

### CROSS-REFERENCE TO RELATED APPLICATIONS

This application is based upon and claims the benefit of priority from the prior Japanese Patent Application No. 2005-071429, filed on Mar. 14, 2005, the entire contents of which are incorporated herein by reference.

### BACKGROUND OF THE INVENTION

1. Field of the Invention

The present invention relates to a medium storage device for recording data on a medium by a head and a write path diagnosis method, and more particularly to a medium storage device for diagnosing a write path when a write command is received, and a write path diagnosis method.

2. Description of the Related Art

Because of the recent demand for computerizing the processing of data, larger capacities are demanded for medium storage devices for storing data, such as magnetic disk devices and optical disk devices. For this reasons the track density and the recording density of the disk medium are increasing more and more. Also high-speed access is demanded. Therefore for a normal write command, write data is stored in the cache memory and completion is reported to the host (so called write cache).

Then the write data of the cache memory is written on the disk, that is, a write back is executed. During this write back as well, a verify check after writing is not executed so as to decrease the wait time of the host. Particularly when the read element and the write element in the head are separated and disposed at positions which offset each other, a rotational delay is required to save the wait time.

For storage devices for reading and writing data on such a recording medium using a head, an improvement of reliability of data is critical today as capacities thereof increase. However in the case of disk devices using cache memory, data is simply written on the recording medium at write back, and it is not confirmed that the data was written correctly.

So if a hardware failure (write disabled status) is generated, such as a disconnection or short of a write system path (signal line for write gate and write processing) of the head, or if a setup mistake for the write system path is generated since the software for executing power save mode has a problem, this write disabled status cannot be detected, and it cannot be confirmed whether the data was written on the medium correctly until the data is read later.

If processing is continued in such a write disabled status, data will be lost, so various methods have been provided for detecting such a write disabled status.

The first conventional method is that the host commands include a command for diagnosing the device, which is called a SMART (Self Monitoring/Analyze Report Technology) test sub-command, and head diagnosis is included as one of the items of this command.

According to this method, write/read/compare (W/R/C) processing of data is performed for the medium based on the head diagnosis items, and if an error is detected in one of these processings, the error is reported to the host. By this, the host can detect that the device is in write disabled status.

The second conventional method is using a general command called a write verify command. This write verify command writes data directly on the disk without executing write cache using a cache memory, then reads this data written on the disk to confirm that reading is possible, and responds the result to the host (e.g. Japanese Patent Application Laid-Open No. 2000-066958).

Because of the recent demands to downsize devices, such a medium storage device is installed in a compact server and mobile equipment (e.g. notebook type personal computers and portable AV (Audio/Visual) equipment). Therefore the packaging density is becoming high and the disconnection and short of a write system path, due to micro particles or vibration during assembly of the device and during operation of the device, are becoming a concern.

For example, if the printed circuit board mounting circuits are outside the disk drive, the signal line for write processing on the printed circuit board may be shorted by particles (e.g. metal particles) when the printed circuit board is built into the device.

In the case of conventional diagnosis by a diagnosis command, the host must issue the command periodically, and this command is executed for all the tracks which require a minute unit level processing time, so performing this diagnosis during normal operation processing is not appropriate. Executing this diagnosis command at startup is still a problem to implement a short standby time after power ON, a requirement which is currently demanded.

With the conventional method of using a write verify command, on the other hand, the write cache cannot be executed, and a rotational delay of the disk is always generated, so the write processing speed, that is the performance, drops considerably. For example, in storing data in the cache memory by write cache, returning the completion of processing to the host which is high-speed processing, cannot be executed, and for sequential writing, the rotational delay of the disk increases and performance drops further.

### SUMMARY OF THE INVENTION

With the foregoing in view, it is an object of the present invention to provide a medium storage device for diagnosing a write path without dropping the performance of the device, and the write path diagnosis method of the medium storage device.

It is another object of the present invention to provide a medium storage device for diagnosing the write path without sending a special command from the host and a write path diagnosis method of the medium storage device.

It is still another object of the present invention to provide a medium storage device for diagnosing the write path in on-line status and detecting the write disabled status at an early stage without dropping performance within the write commands from the host, and a write path diagnosis method of the medium storage device.

It is still another object of the present invention to provide a medium storage device for diagnosing a write path, just like retry processing, without causing the host to wait, and a write path diagnosis method of the medium storage device.

To achieve these objects, the medium storage device of the present invention has a head for either reading or writing data on the tracks of a storage medium, an actuator for positioning the head onto a desired track of the storage medium, a data memory for storing write data from the host, and a control unit for storing the write data from the host to the data memory according to a write command from the host, returning a response to the host, and then writing the write data in the data memory to the storage medium by the head. And after writing of the data to the storage medium completes, the control unit reads partial data including the final portion of the write data of the storage medium, and compares the partial data with data in the data memory to perform diagnosis processing for a write path.

The write path diagnosis method of the present invention is a write system path diagnosis method for a medium storage device which either reads or writes data on the tracks of a storage medium by a head, having a step of storing write data from a host in a data memory according to a write command from the host, and returning a response to the host, a step of writing the write data in the data memory in the storage medium by the head, a step of reading partial data including the final portion of the write data of the storage medium after writing of the write data on the storage medium completes, comparing the partial data with the data in the data memory, and performing diagnosis processing for a write path.

In the present invention, it is preferable that the control unit performs replacement processing of a defective sector, and executes the diagnosis processing using the replacement processing.

In the present invention, it is also preferable that the control unit has a controller which communicates with the host and controls data transfer between the data memory, the host, and the head, and an MPU which instructs the writing and communication with the host to the controller, and the MPU executes the diagnosis processing of the write path.

In the present invention, it is preferable that the control unit further has a memory for storing the diagnosis request information, and executes the diagnosis processing for the write path when the diagnosis request information is set in the memory.

In the present invention, it is also preferable that the control unit resets the diagnosis request information in the memory after executing the diagnosis processing.

In the present invention, it is also preferable that the memory respectively stores the diagnosis request information of a plurality of heads, and the control unit executes the diagnosis processing by referring to the diagnosis request information of a head which executes the writing of the write data.

In the present invention, it is also preferable that the control unit resets the diagnosis request information of the head in the memory after executing the diagnosis processing of the head.

In the present invention, it is also preferable that the control unit executes the diagnosis processing at a predetermined time interval.

In the present invention, it is also preferable that partial data of the write data is the final sector of the write data.

In the present invention, it is also preferable that the control unit executes the replacement processing when reading the partial data of the write data of the diagnosis processing does not succeed.

In the present invention, it is also preferable that the head has a read element for reading a magnetic medium and a write element for writing on the magnetic medium.

In the present invention, a partial data (e.g. final sector) including a final portion of the written data is read/compared when the data is written back from the data memory to the storage medium using the write cache. Therefore when the write data written in the data memory is written back by the write command of the host, the write path can be diagnosed without affecting the host. Also all the write data is not the target of the diagnosis of the write path, but the partial data including the final portion is the target, so diagnosis can be performed in a short time, and even if the write data is received because sequential writing exceeded the capacity of the cache memory, the data is not overwritten on the cache memory, because the final portion is used, and the write system path can be diagnosed with certainty.

### BRIEF DESCRIPTION OF THE DRAWINGS

FIG. 1 is a block diagram depicting the medium storage device according to an embodiment of the present invention;

FIG. 2 is a diagram depicting the write system path in FIG. 1;

FIG. 3 is a table explaining the diagnosis request flag table in FIG. 1;

FIG. 4 is a diagram depicting the diagnosis method for the write path according to an embodiment of the present invention;

FIG. 5 is a diagram depicting the diagnosis method for the write path according to another embodiment of the present invention;

FIG. 6 is a flow chart depicting the write back processing according to an embodiment of the present invention;

FIG. 7 is a flow chart depicting the replacement processing in FIG. 6; and

FIG. 8 is a flow chart depicting the diagnosis request flag clear processing in FIG. 6.

### DESCRIPTION OF THE PREFERRED EMBODIMENTS

Embodiments of the present invention will now be described in the sequence of the medium storage device, write system path diagnosis method, write back processing and other embodiments.

Medium Storage Device

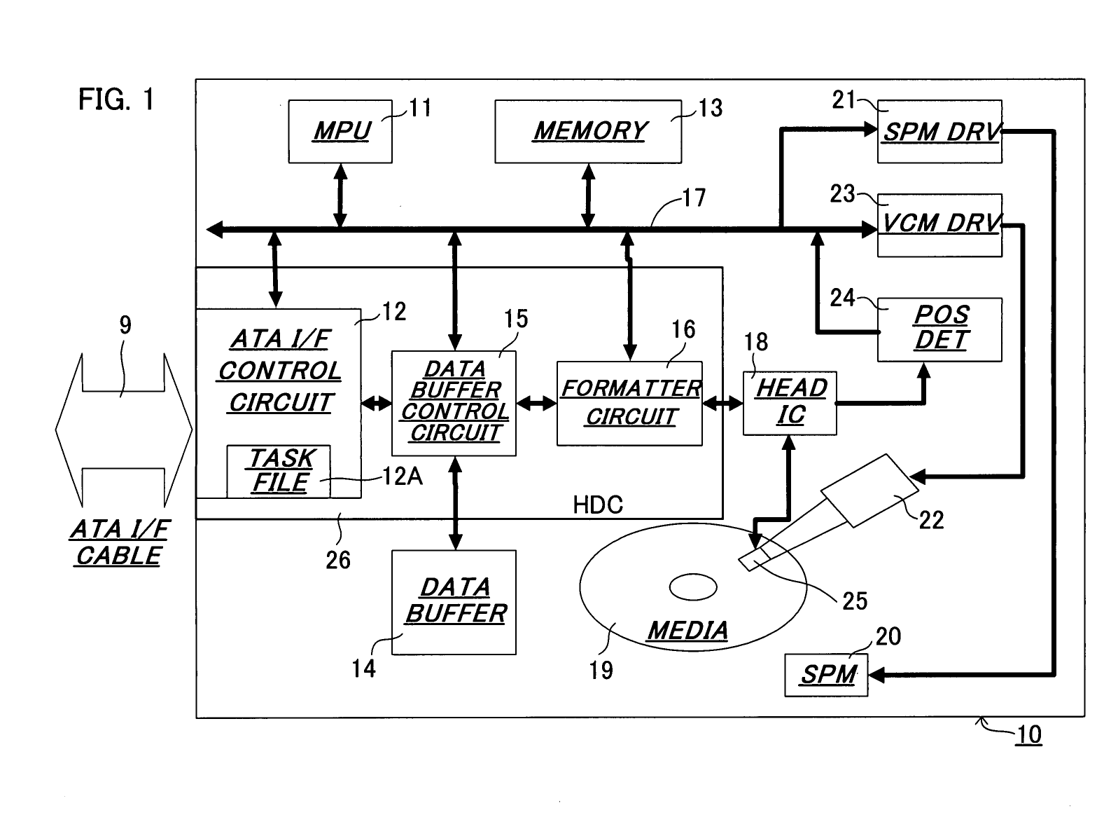

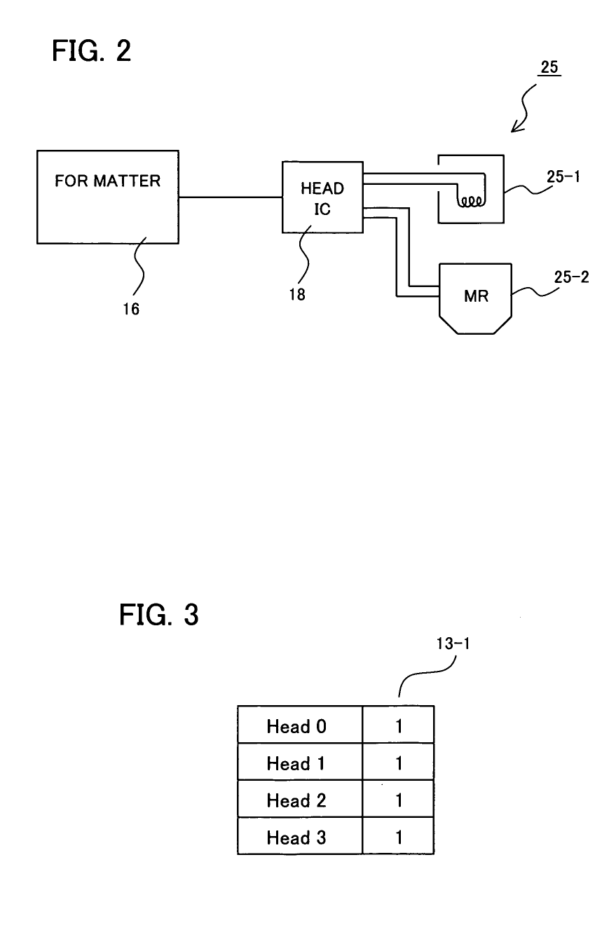

FIG. 1 is a block diagram depicting the medium storage device according to an embodiment of the present invention, FIG. 2 is a diagram depicting the write system path in FIG. 1, and FIG. 3 is a table explaining the diagnosis request flag table in FIG. 1. FIG. 1 shows the magnetic disk device (HDD) for reading/writing data on the magnetic disk as an example of the medium storage device.

FIG. 1 shows the magnetic disk device 10 built into a personal computer, and is connected with the host (not illustrated) of the personal computer via the ATA (AT Attachment) standard interface cable 9.

The magnetic disk device 10 is comprised of a magnetic disk 19, a spindle motor 20 for rotating the magnetic disk 19, a magnetic head 25 for reading/writing data on the magnetic disk 19, and an actuator (VCM) 22 for moving the magnetic head 25 in a radius direction (track crossing direction) of the magnetic disk 19.

The control unit is comprised on an HDC (Hard Disk Controller) 26, a data buffer 14, an MPU 11, a memory (RAM) 13, a head IC 18, a spindle motor driver 21, a VCM driver 23, a position detection unit 24, and a bus 17 connecting these composing elements.

The HDC 26 is further comprised of an ATA interface control circuit 12 which has a task file 12A for setting a task from the host, a data buffer control circuit 15 for controlling the data buffer 14, and a formatter control circuit 16 for controlling the format of the recorded data.

The data memory (called the data buffer) 14 plays a role of the cache memory, and stores the write data from the host and stores the read data from the magnetic disk 19. In other words, the data buffer 14 plays a role of the write cache and the read cache. During write back, the write data of the data buffer 14 is written on the magnetic disk 19, and during reading the read data in the data buffer 14 is transferred to the host.

The head IC 18 supplies recording current to the magnetic head 25 according to the recording data during write, and amplifies the read signal from the magnetic head 25 and outputs read data (including servo information) during read. The position detection unit 24 detects the position of the magnetic head 25 from the servo information from the head IC 18.

The spindle motor driver 21 rotary-drives the spindle motor 20. The VCM driver 23 drives the VCM 22 for moving the magnetic head 25. The MPU (Micro Processing Unit) 11 performs the position control of the magnetic head 25, the read/write control and the retry control. The memory (RAM) 13 stores the data necessary for the processing of the MPU 11. The memory 13 also stores the diagnosis request flag table 13-1, which will be described later in FIG. 3.

FIG. 2 is a diagram depicting the write system path in FIG. 1. The magnetic head 25 is a head where the read element 25-2 and the write element 25-1 are separated, and the read element 25-2 is comprised of an MR (Magneto-Resistive) element, and the write element 25-1 is comprised of an induction element further comprising a magnetic core and coil.

In the write system path, the formatter control circuit 16 is connected to the head IC 18 via the first signal line, and the head IC 18 is connected to the write element 25-1 via the second signal line. The head IC 18 is also connected to the read element 25-2 via the third signal line. This head IC 18 is normally mounted on the suspension supporting the magnetic head 25.

In this write system path, a disconnection or short may occur in the first signal line and the second signal line. Also in the formatter control circuit 16, power may not be supplied when returning from power save mode because of a software problem in power save mode. For certain writing may be disabled by a deterioration of the write element 25-1 itself.

FIG. 3 is a table explaining the diagnosis request flag table 13-1 in FIG. 1, and the diagnosis request flag is stored for each head. In this example, four heads, HEAD 0-3, have been installed, and flag “0” indicates a diagnosis request and “1” indicates a diagnosis completion.

Write System Path Diagnosis Method

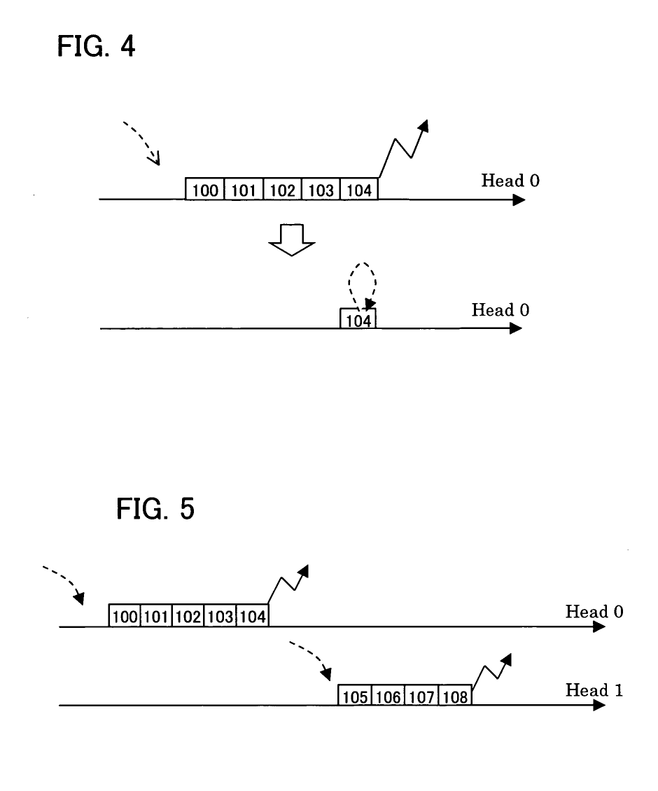

FIG. 4 is a diagram depicting the operation of the write system path diagnosis method. FIG. 4 shows an example of writing five sectors from LBA (Logical Block Address) 100 using the head 0. As FIG. 4 shows, when five sectors from LBA 100, that is up to LBA 104, are written by the head 0, the firmware refers to the diagnosis flag and judges whether a diagnosis has been requested. If diagnosis has been requested, the firmware requests the dummy replacement processing for the final sector as if an error occurred.

In this replacement processing, the final sector is verified. In this verification, the data on the final sector is read by the head 0 and is compared with the write data. If a comparison result matches, the replacement processing is cancelled. If a read error occurs, it is judged that the final sector is a defective sector, and normal replacement processing is performed. If the comparison result is not good, it is judged as a write system path failure, and the problem is handled as a write error.

In this way, the final sector of the data written on a track is used as a dummy replacement target, and read/compare is executed by specifying the diagnosis request flag. Therefore when the write data written in the cache memory is written back by the write command of the host, the write system path can be diagnosed without affecting the host.

Since the final sector, instead of all the write data, is the target of the diagnosis of the write system path, diagnosis in a short time can be implemented, and a drop in performance can be minimized. Also by using a replacement processing routine, installing this method in the device is easy.

FIG. 5 is a diagram depicting the diagnosis request in write processing extending over a plurality of heads. FIG. 5 shows an example when nine sectors are written, where five sectors from LBA 100 are written by the head 0, and four sectors from LBA 105 are written by a different head 1. As FIG. 5 shows, when the five sectors from LBA 100, that is up to LBA 104, are written by the head 0, the firmware refers to the diagnosis flag, and judges whether diagnosis has been requested. If diagnosis has been requested, the firmware requests a dummy replacement processing for the final sector 104 by the head 0 as if an error occurred.

When four sectors from LBA 105, that is, up to LBA 108, are written by the head 1, the firmware refers to the diagnosis flag, and judges whether a diagnosis has been requested. If diagnosis has been requested, the firmware requests a dummy replacement processing for the final sector 108 by the head 1 as if an error occurred.

In this replacement processing, the final sector is verified as mentioned above. In this verification, the data on the final sector is read by the head, and is compared with the write data. If the comparison result matches, the replacement processing is cancelled. If a read error occurs, it is judged that the final sector is a defective sector, and normal replacement processing is performed. If the comparison result is not good, it is judged as a write system path failure, and the problem is handled as a write error.

In this way, even in the case of write processing extending over a plurality of heads, the final sector of the data written by a head is used as a dummy replacement target, and read/compare is executed by specifying a diagnosis request flag. Therefore when the write data written in the cache memory is written back by the write command of the host, the write system path can be diagnosed without affecting the host. In other words, in this case write system paths by two heads can be diagnosed.

Write Back Processing

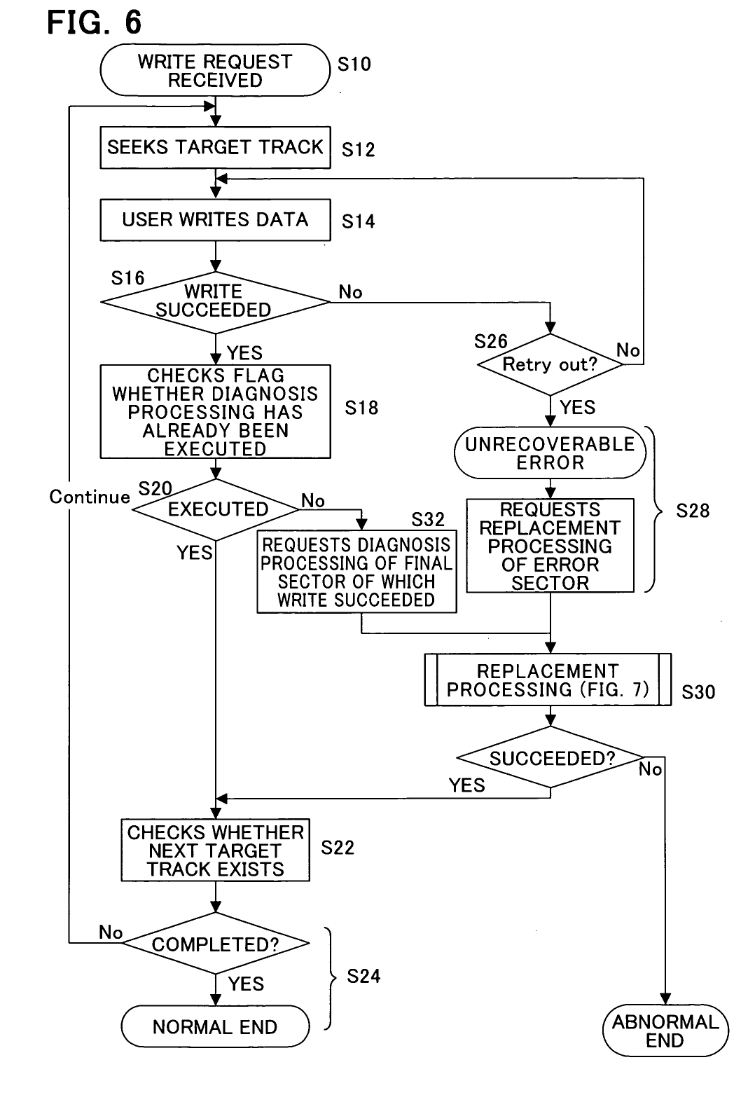

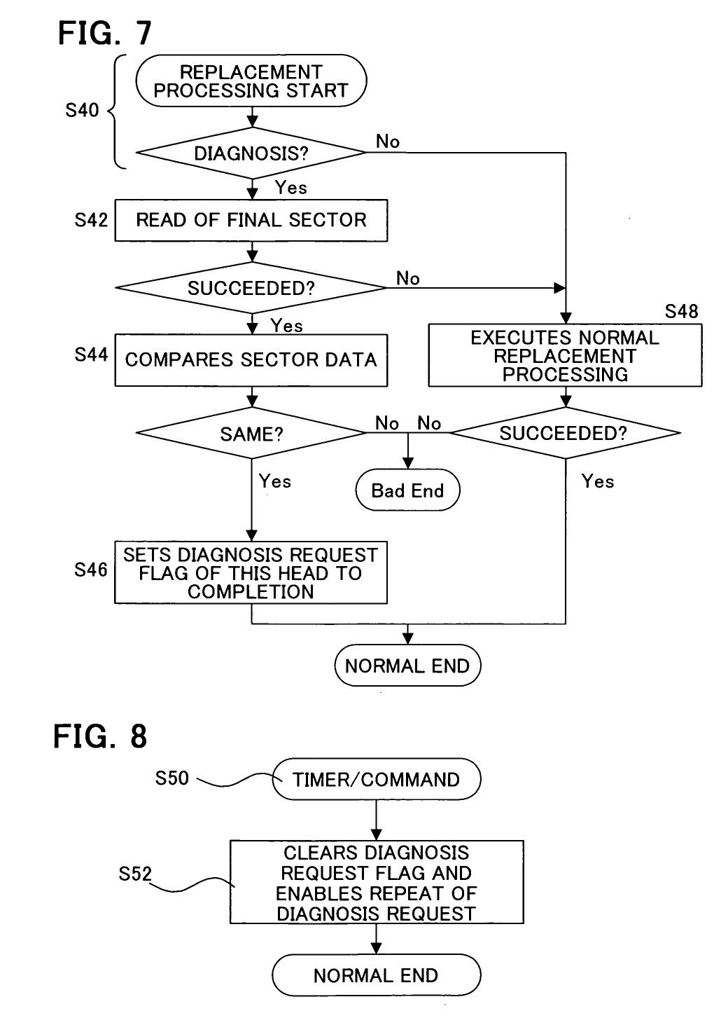

FIG. 6 is a flow chart depicting the medium write (write back) processing according to an embodiment of the present invention, FIG. 7 is a flow chart depicting the replacement processing in FIG. 6, and FIG. 8 is a flow chart depicting diagnosis request flag clear processing.

(S10) When a write command is received from the host and the write data is stored in the buffer memory 14, write back, that is writing the write data on the medium, is started.

(S12) The MPU 11 drives the VCM 22 via the VCM driver 23, and seeks (track change, head change) up to a predetermined position (track) on the medium 19.

(S14) The MPU 11 instructs the HDC 26 to execute medium write, and the HDC 26 sends the write data in the buffer memory 14 to the magnetic head 25 (the write element 25-1 in FIG. 2) via the head IC 18, and executes write back. If the data extends over a plurality of tracks, the data on the applicable track is written on the medium.

(S16) The MPU 11 judges whether the medium write on the applicable track succeeded (no error in medium write processing). This error in medium write processing is the case when writing is not possible because of an off track, so the data itself is not verified.

(S18) If the medium write on the applicable track succeeded, the MPU 11 judges whether a diagnosis processing is required for the head positioning on the track by a flag of the diagnosis request flag table 13-1 of the memory 13. Since it is judged whether diagnosis processing is required here, if the medium write requested by the host exceeds over a plurality of tracks or a plurality of heads, diagnosis is executed for each track or for each head.

(S20) If it is judged that a diagnosis processing for a head is unnecessary by the flag (flag is “1”), the MPU 11 continues normal processing.

(S22) In other words, the MPU 11 judges whether all the requested data has been written on the medium (whether a track change or head change is required).

(S24) If all the requested data has been written on the medium, the MPU 11 ends the processing normally, and if processing is still continuing, the processing returns to step S12.

(S26) If an error is detected during medium write in step S16, the MPU 11 executes retry processing (returns to step S14). In other words, the MPU 11 judges whether the retry count reached a predetermined count, and if not the processing returns to step S14, and if reached, a retry out occurs.

(S28) If a retry out occurs, which is regarded as an unrecoverable error, the MPU 11 requests replacement processing for a recoverable sector.

(S30) The MPU 11 calls up the replacement processing, which will be described in FIG. 7, executes the replacement processing, and judges whether the replacement processing succeeded. If the replacement processing failed, the MPU 11 reports the error to the host, and ends the processing as an abnormal end. If the replacement processing succeeded, the processing advances to step S22.

(S32) If the medium write on the applicable track succeeded and diagnosis processing is requested in step S20, the MPU 11 requests diagnosis processing for the final sector of the data written on the medium on that track. Since the diagnosis processing is integrated into the replacement processing, processing is the same as the case when the final sector of the data written on the medium on that track became an error (actually no error occurred). In other words, the MPU 11 requests diagnosis processing and the processing advances to step S30.

Now the replacement processing in FIG. 6 will be described with reference to FIG. 7.

(S40) When a replacement processing module is called up in Step S30, it is judged whether this is normal replacement processing (caused by an error) or a diagnosis request.

(S42) It if is a diagnosis request, the MPU 11 reads the applicable sector (final sector) from the magnetic disk 19 using the magnetic head 25. And the MPU 11 judges whether the medium read succeeded (no servo error, ECC error or other error occurred).

(S44) If it is judged that the medium read succeeded, the MPU 11 compares the data read from the medium 19 and the data written on the medium which remains on the buffer 14, and judges whether they are the same. If different, the processing ends abnormally, regarding this as the write system path is abnormal.

(S46) If the data written on the medium 19 and the data read from the medium 19 match, the MPU 11 changes the flag for the head used for this sector to indicate the completion of diagnosis processing. In other words, in FIG. 3, the flag is set to “1”. This indicates that hereafter diagnosis is unnecessary for this head. And the processing ends normally.

(S48) If it is judged in step S40 that this replacement processing is not for diagnosis (the case of a normal replacement request), the replacement processing is executed. The case when the replacement processing was for a diagnosis request step S42, but an error was detected in the medium read, is also included in this processing. In the replacement processing, the applicable error sector is the replacement source, and the data on the buffer, which was to be written to the replacement source sector, is written to the replacement destination sector. The MPU 11 judges whether the replacement processing succeeded. In this replacement processing, the data is written to the medium, the data is read from the medium, both data are compared, and it is judged whether the replacement processing succeeded. If the requested replacement processing failed, the processing ends abnormally, and if the replacement processing succeeds, the processing ends normally.

In this way, whether diagnosis is requested is judged referring to the diagnosis flag, and if diagnosis is requested, a dummy replacement processing for the final sector is requested as if an error occurred. In this replacement processing, the final sector is verified, that is the data of the final sector is read by the head, and is compared with the write data on the buffer. If the comparison result matches, the replacement processing is cancelled. If a read error occurs, the final sector is judged as a defective sector and normal replacement processing is performed. If the comparison result is not good, it is judged as a write system path failure, and this problem is handled as a write error.

In this way, the final sector of the data written by a head is used as a dummy replacement target, and read/compare is executed by specifying the diagnosis request flag. Therefore when the write data written in the cache memory is written back by the write command of the host, the write system path can be diagnosed without affecting the host.

Since the final sector, instead of all the write data, is the target of the diagnosis of the write system path, diagnosis in a short time can be implemented and a drop in performance can be minimized. Also by using a replacement processing routine, installing this method in the device is easy.

Now the processing of the diagnosis request flag, to indicate the presence of a diagnosis request, will be described with reference to FIG. 8.

(S50) This processing is started by the timer or by a setup command from the host. In other words, this processing is started by the timer if the diagnosis is executed by the device itself periodically, and is started by a setup command from the host if the diagnosis is executed by an instruction from the host.

(S52) The MPU 11 clears the diagnosis request flag (“0”) of the diagnosis request flag table 13-1 in the memory 13, to change to unexecuted (diagnosis request) status. By this, diagnosis processing is executed again in the next medium write processing. Depending on the type of setup command, only an interval of the timer may be set again. And the setting of the timer or a setup command from the host is completed.

Because of this, diagnosis can be executed periodically. The timing of diagnosis can also be specified from the host.

### Other Embodiments

In the above embodiments, the comparison target is the final sector, but it need not be one final sector but one or two or more sectors, including the final sector having partial data of the write data, may be used. If the minimum write unit is not a sector but a half-sector (e.g. split sector system) as well, one or two or more minimum write unit areas, including the area in the final write unit having partial data of the write data, may be used.

The medium storage device was described using the magnetic disk device, but the present invention can also be applied to a storage device using an optical disk, magneto-optical disk or another storage medium. The interface is not limited to ATA, but other interfaces can be used. The present invention can also be applied to a method that does not use a replacement processing module.

The present invention was described using the embodiments, but the present invention can be modified in various ways within the scope of the essential character of the present invention, and these shall not be excluded from the scope of the present invention.

After the write cache is executed by a host command, read/compare is executed for partial data, including the final portion of the written data when the data is written back from the data memory to the storage medium, so the write system path can be diagnosed without affecting the command response of the host. And the final sector, instead of all the write data, is the target of diagnosis of the write system path, so diagnosis in a short time can be implemented, a drop in performance can be minimized, write disabled status can be diagnosed in a short time at an early stage, and the write system path can be diagnosed with certainty even for a sequential write which exceeds the capacity of the data memory.

What is claimed is:

1. A medium storage device, comprising:
a head for either reading or writing data on tracks of a storage medium;
an actuator for positioning said head on a desired track of said storage medium;
a data memory for storing write data from a host; and
a control unit for storing the write data from said host to said data memory according to a write command from said host, returning a response to said host, and then writing said write data in said data memory to said storage medium by said head,
wherein after writing of said write data to said storage medium completes, said control unit reads partial data including the final portion of said write data of said storage medium, and compares the partial data with data in said data memory to perform diagnosis processing for write path.

2. The medium storage device according to claim 1,
wherein said control unit performs replacement processing of a defective sector, and executes said diagnosis processing using said replacement processing.

3. The medium storage device according to claim 1,
wherein said control unit comprises:
a controller which communicates with said host and controls data transfer among said data memory, said host and said head; and
an MPU which instructs said writing and communication with said host to said controller and executes diagnosis processing of said write path.

4. The medium storage device according to claim 1,
wherein said control unit further comprises a memory for storing diagnosis request information and executes the diagnosis processing for said write path when said diagnosis request information is set in said memory.

5. The medium storage device according to claim 4,
wherein said control unit resets said diagnosis request information in said memory after executing said diagnosis processing.

6. The medium storage device according to claim 4,
wherein said memory respectively stores said diagnosis request information of a plurality of heads, and
said control unit executes said diagnosis processing by referring to said diagnosis request information of a head which executes the writing of said write data.

7. The medium storage device according to claim 6,
wherein said control unit resets the diagnosis request information of said head in said memory after executing the diagnosis processing of said head.

8. The medium storage device according to claim 1,
wherein said control unit executes said diagnosis processing at a predetermined time interval.

9. The medium storage device according to claim 1,
wherein said control unit reads the final sector as partial data of said write data.

10. The medium storage device according to claim 2,
wherein said control unit executes said replacement processing when reading the partial data of said write data of the diagnosis processing does not succeed.

11. The medium storage device according to claim 1,
wherein said head comprises:
a read element for reading a magnetic medium; and
a write element for writing on said magnetic medium.

12. A write path diagnosis method for a medium storage device which either reads or writes data on tracks of a storage medium by a head, comprising the steps of:
storing write data from a host in a data memory according to a write command from said host and returning a response to said host;
writing said write data in said data memory in said storage medium by said head;
reading partial data including the final portion of said write data of said storage medium after writing of said write data on said storage medium completes; and
comparing the partial data with the data in said data memory, and performing diagnosis processing for the write path.

13. The write path diagnosis method for a medium storage device according to claim 12,
wherein the step of performing said diagnosis processing comprises a step of executing said diagnosis processing using a replacement processing of a defective sector.

14. The write path diagnosis method for a medium storage device according to claim 12,
wherein the step of storing said write data in said data memory and the step of writing the data from said data memory to said storage medium are executed by a controller which communicates with said host and controls the data transfer among said data memory, said host and said head,
and the step of diagnosing said write system path is executed by an MPU which instructs said writing and communication with said host to said controller.

15. The write path diagnosis method for a medium storage device according to claim 12,
wherein said diagnosis processing step further comprises:
a step of referring to a memory for storing said diagnosis request information; and
a step of executing the diagnosis processing of said write path when said diagnosis request information is set in said memory.

16. The write path diagnosis method for a medium storage device according to claim 12, wherein said diagnosis processing step further comprises:
a step of referring to said memory for respectively storing said diagnosis request information of a plurality of heads; and
a step of executing said diagnosis processing according to said diagnosis request information of a head which executes the writing of said write data.

17. The write path diagnosis method for a medium storage device according to claim 15 and claim 16, further comprising a step of resetting the diagnosis request information of said head in said memory after executing the diagnosis processing of said head.

18. The write path diagnosis method for a medium storage device according to claim 12,
further comprising a step of executing said diagnosis processing step at a predetermined time interval.

19. The write path diagnosis method for a medium storage device according to claim 13,
further comprising a step of executing said replacement processing when reading the partial data of said write data in said diagnosis processing does not succeed.

20. The write path diagnosis method for a medium storage device according to claim 12,
wherein said diagnosis processing step further comprises a step of diagnosing the write path of the head which is constructed by a read element for reading a magnetic medium and a write element for writing on said magnetic medium.
